(19) United States
(12) Patent Application Publication
(10) Pub. No.: US 2025/0112191 A1
(43) Pub. Date: Apr. 3, 2025

(54) DIRECT DIE-TWO-DIE CONNECTION THROUGH AN INTERPOSER WITHOUT VIAS

(71) Applicant: Intel Corporation, Santa Clara, CA (US)

(72) Inventors: Thomas WAGNER, Regelsbach (DE); Pouya TALEBBEYDOKHTI, Mesa, AZ (US); Stephan STOECKL, Schwandorf (DE); Lizabeth KESER, San Diego, CA (US)

(21) Appl. No.: 18/374,920

(22) Filed: Sep. 29, 2023

(51) Int. Cl. H01L 23/00; H01L 21/48; H01L 23/13; H01L 23/48; H01L 23/498; H01L 25/00; H01L 25/065; H01L 25/10

(52) U.S. Cl. CPC H01L 24/16; H01L 21/4853; H01L 23/13; H01L 23/49811; H01L 24/05; H01L 24/06; H01L 24/13; H01L 24/14; H01L 25/0657; H01L 25/105; H01L 25/50; H01L 23/481; H01L 2224/0557; H01L 2224/06181; H01L 2224/13005; H01L 2224/13014; H01L 2224/13016; H01L 2224/13082; H01L 2224/13147; H01L 2224/13611; H01L 2224/1403; H01L 2224/14051; H01L 2224/16141; H01L 2224/16227; H01L 2224/17181; H01L 2225/06513; H01L 2225/06517; H01L 2225/0652; H01L 2225/06572; H01L 2924/2064; H01L 2924/20641; H01L 2924/20642; H01L 2924/20643; H01L 2924/20752; H01L 2924/20753; H01L 2924/20754; H01L 2924/20755

(57) ABSTRACT

A semiconductor package comprises an interposer with at least one open area through the interposer. A first die is connected to a first side of the interposer. A second die is connected to a second side of the interposer. At least one metal pillar is connected to the first die that extends through the open area of the interposer and connects to the second die to provide a direct die-to-die connection through the interposer.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips.

Integrated circuit(s), such as chiplets that contain a well-defined subset of functionality, may be packaged on a semiconductor package. The semiconductor package may be integrated onto an electronic system, such as a consumer electronic system. Today, high-performance CPUs and special application processors are more likely to be built with a disaggregated architecture using multiple chiplets connected via an interposer in order to reduce die sizes which results in higher yields and lower costs. Also, process nodes can be selected to optimize for each chiplet also resulting in reduced costs. In some applications, the chiplets are not only placed next to each other in an array but also face-to-face. For example, typically memory or Integrated Passive Device (IPD) dies are placed on the opposite site of an interposer, for example, to have a minimum distance between the active areas.

One drawback is that such an architecture requires an interposer that have several redistribution layers (RDLs) through which one die on the bottom side of the interposer must connect with a second die on the top side of the interposer. Multiple connections from the bottom side die to the topside die must be made through all the redistribution layers of the interposer using multiple vias and solder balls. This results in the buildup of contact resistance because of all the different contact interfaces.

### BRIEF DESCRIPTION OF THE DRAWINGS

FIG. 1A depicts a simplified cross-sectional schematic diagram illustrating a state-of-the-art semiconductor package having a disaggregated product architecture, with opposite die placements on an interposer in accordance with example embodiments of the disclosure.

FIG. 1B illustrates a view of example types of interconnections between logic dies through a multi-layer interposer.

FIG. 2A depicts a simplified cross-sectional schematic diagram illustrating a semiconductor package with a direct die-to-die connection through an interposer without vias according to one embodiment.

FIG. 2B depicts a simplified cross-sectional schematic diagram illustrating a semiconductor package where each of the dies includes tall pillars to provide a direct die-to-die connection through the open area in the interposer according to a further embodiment.

FIGS. 3A-3D illustrate views of various stages in a method of fabricating a direct die-to-die connection through an interposer in accordance with an embodiment of the present disclosure.

FIGS. 4A-4G illustrate the further details for fabricating the interposer with at least one open area.

FIGS. 5A-5C illustrate simplified cross-sectional schematic diagrams illustrating a semiconductor package in various embodiments.

FIGS. 6A and 6B illustrate a wafer composed of semiconductor material and may include one or more dies having integrated circuit (IC) structures formed on the surface of the wafer.

FIG. 7 illustrates a block diagram of an electronic system, in accordance with an embodiment of the present disclosure.

FIG. 8 is a cross-sectional side view of an integrated circuit (IC) device assembly that may include a substrate with direct die-two-die connection through an interposer without vias, in accordance with one or more of the embodiments disclosed herein.

FIG. 9 illustrates a computing device in accordance with one implementation of the disclosure.

### DESCRIPTION OF THE EMBODIMENTS

Direct die-two-die connections through an interposer without vias are described. In the following description, numerous specific details are set forth, such as specific material and tooling regimes, in order to provide a thorough understanding of embodiments of the present disclosure. It will be apparent to one skilled in the art that embodiments of the present disclosure may be practiced without these specific details. In other instances, well-known features, such as single or dual damascene processing, are not described in detail in order to not unnecessarily obscure embodiments of the present disclosure. Furthermore, it is to be understood that the various embodiments shown in the Figures are illustrative representations and are not necessarily drawn to scale. In some cases, various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Embodiments of the disclosure may provide a semiconductor package and a method for fabrication of the semiconductor package. The disclosed embodiments include an open area through an interposer. Two dies are mounted on opposite sides of the interposer and one or both of the dies include a tall pillar attached to a pillar microbump. The tall pillars and the attached pillar microbumps extend through the open area of the interposer and directly connect to the opposite die, thereby providing a direct-to-direct connection without vias.

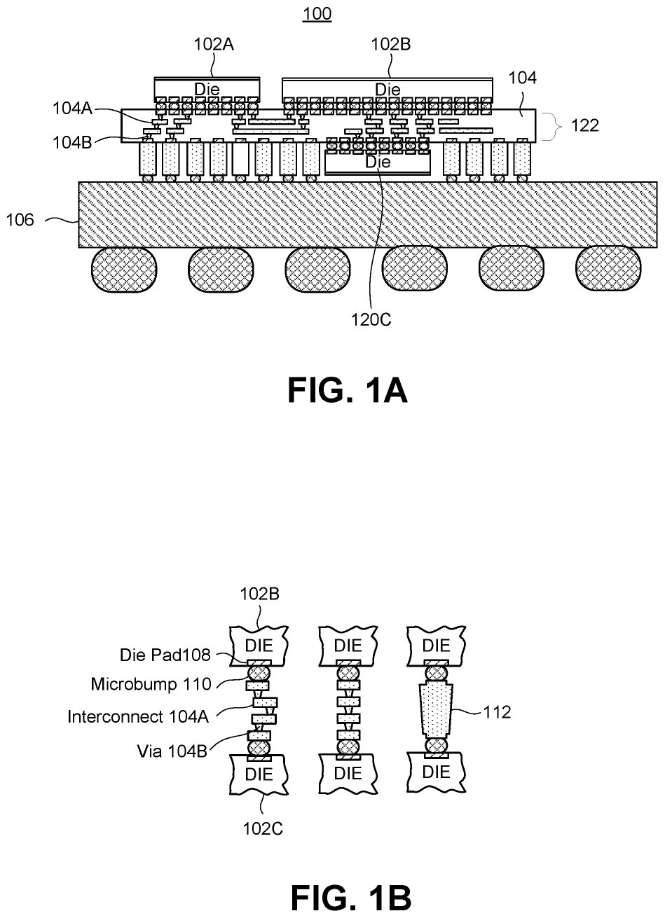

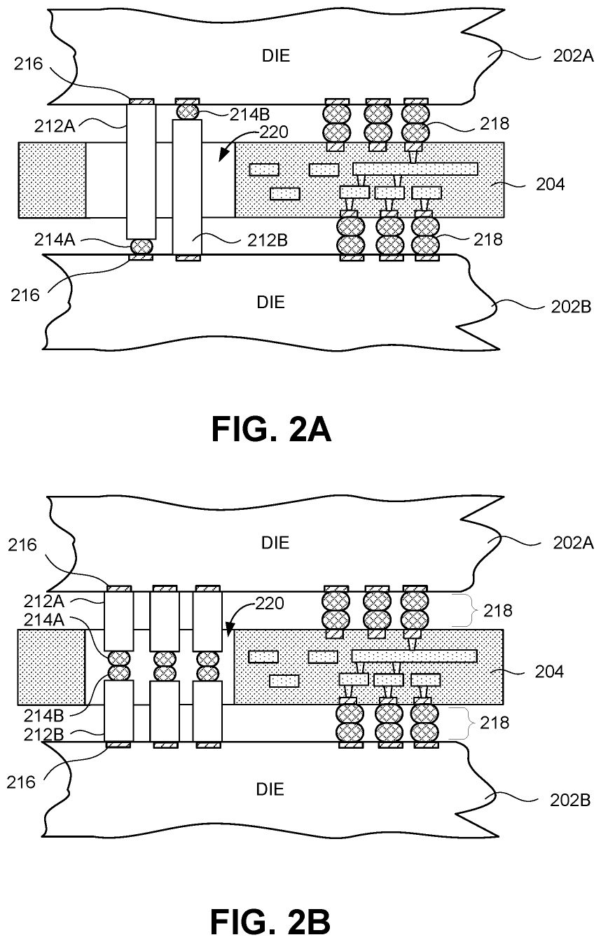

To provide context, FIG. 1A depicts a simplified cross-sectional schematic diagram illustrating a state-of-the-art semiconductor package 100 having a disaggregated product architecture, with opposite die placements on an interposer in accordance with example embodiments of the disclosure. The semiconductor package 100 include one or more logic die, such as logic die 102A (e.g., a graphic die) and logic die 102B (e.g., a CPU or SoC die) coupled to a top side an interposer 104, and logic die 102C (e.g., a memory die) coupled to a bottom side of the interposer 104. Interposer 104, in turn, is connected to a substrate 106 through large pitch bumps.

The interposer 104 may have a core comprising one or more redistribution layers (RDLs) 122, each of which may have one or more interconnects 104A. Vias 104B are used to connect the interconnects 104A between adjacent RDLs 122. The interconnects 104A may provide electrical pathways for signals between electronic components (e.g., integrated circuits, passive devices, etc.), input/output (I/O) connections on the semiconductor package, signal fan out from/to the electronic components, signal connections between two or more electrical components, power delivery to electrical component(s), ground connections to electrical component(s), clock signal delivery to the electrical component(s), combinations thereof, or the like.

The RDLs can be symmetric on both sides or asymmetric. Although two RDLs 122 are shown here, it will be appreciated that there may be any suitable number of 122 in the interposer 104. In one embodiment, the interposer 104 may comprise silicon, glass, or ajinomoto-build-up-film (ABF) material or other organic materials.

For high-frequency signals within the semiconductor package 100, the length of the die-to-die connections and the trace and via structures are very important. Therefore, one semiconductor package architecture option is to place a memory die (e.g., die 102C), for example, on the opposite side of the interposer 104 in the die shadow of a CPU die (e.g., die 102B). This allows the connected signals to be very short, as the connections need to pass only through the thickness of the interposer 104, which can be even below 100 μm.

Accordingly, signals to/from the logic die 102B are coupled to logic die 102C on the bottom side of the interposer 104 through interconnects 104A and vias 104B. The signal quality of these interconnects depends on the physical structure of these connections, where angles of shapes, the roughness of traces, the diversity of materials, or the structure of the vias 104B can lead to signal degradation (e.g. reflections or increased impedances) in addition to surrounding routing. This can result in a slower signal speed over this connection or the need for increased driver strength on the silicon, which has negative impacts on the performance or increase the area and power consumption or other factors.

FIG. 1B illustrates a view of example types of interconnections between logic dies 102B and 102C to RDLs of the interposer 104. Each of the logic dies 102B and 102C include a plurality of die pads 108 (typically internal to the die) connected to corresponding microbumps 110. In one embodiment, the microbumps 110 may comprise plated copper or tin. A common way to create routing traces between the two sets of microbumps 110 is to create a stack vias 104B to connect the interconnects 104A in the RDLs comprising the interposer 104. The vias 104B may be offset from one another between the RDLs, or stacked in a vertical column, as shown. Another possibility to connect the microbumps 110 of two logic dies 102 is through the use of a hole via 112, where after or during the interposer manufacturing process holes are drilled through the entire interposer or some layers and filled with conductive material.

The examples of the die-to-die connection via the microbumps 110 illustrated in FIG. 1B all require a minimum of two transition contact resistors, meaning that two logic die 102 on opposite sides of the interposer 104 are connected by a set of two microbumps 110 connected by one or more vias 104B.

Previous solutions that attempt to improve the interconnect and associated resistance using stacked vias have a higher risk for cracks on contact areas of vias due to thermo-mechanical forces. Through hole vias are larger in diameter drilling due to manufacturing limitations and need therefore more area, resulting often in larger die pad/bump pitches and looser signal density. Both of these have the common disadvantage of a minimum of two transitions of via solder material resulting in added contact resistance, as both dies need to be connected to the interposer, i.e., die bump—solder—copper via(s)—solder—die bump.

In accordance with one or more embodiments, a semiconductor package structure having a direct die-to-die connection through an interposer without vias is disclosed that improves the die-to-die interface and minimizes the disadvantages described above. The disclosed embodiments include an open area through an interposer, preferably in an area without interconnects. Two dies are mounted on opposite sides of the interposer and one or both of the dies include a tall pillar attached to a pillar microbump. The tall pillars and the attached pillar microbumps extend through the open area of the interposer and directly connect to the opposite die. For die-to-die signals, the tall pillars reduce the transition contact resistance to only one solder interface, which reduces also signal reflection as no vias are required.

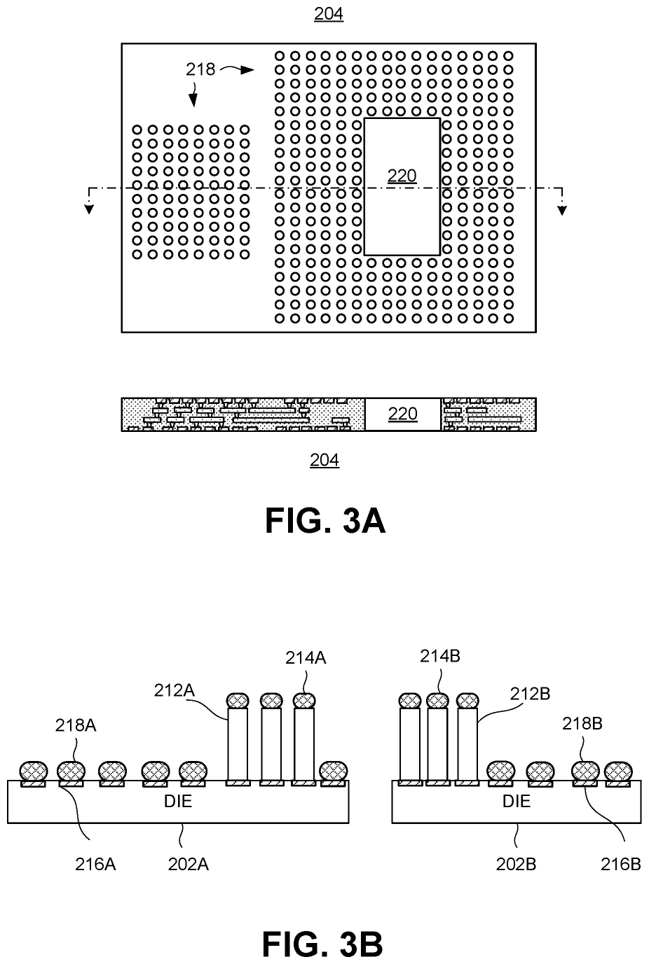

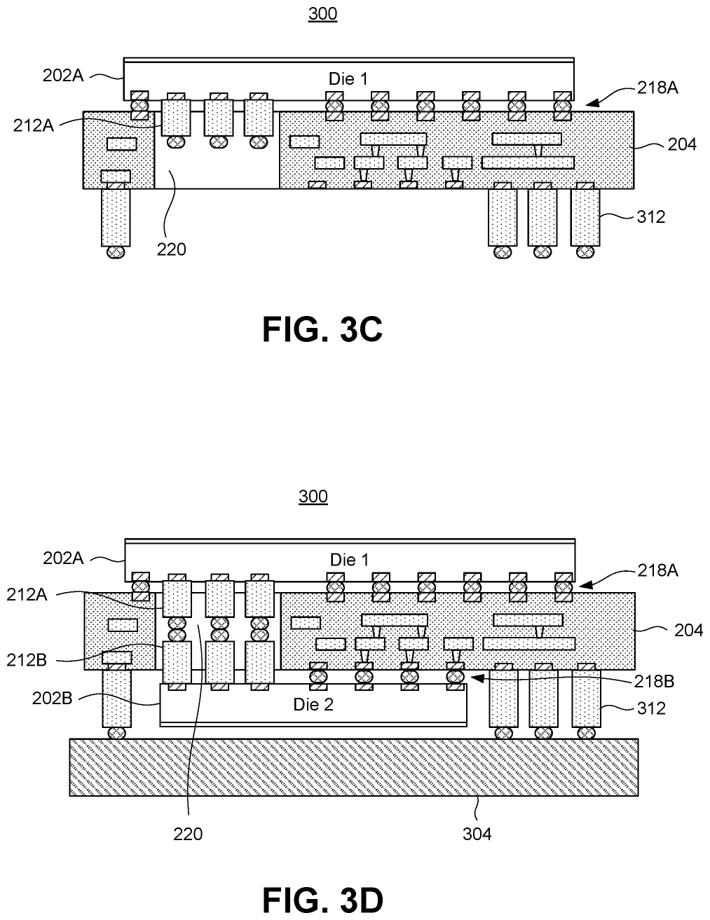

FIG. 2A depicts a simplified cross-sectional schematic diagram illustrating a semiconductor package with a direct die-to-die connection through an interposer without vias according to one embodiment. An interposer 204 includes at least one open area 220 through the interposer 204. The interposer 204 comprises several RDLs and is used to route remaining signals, e.g. power, ground, and signals to other dies. A first die 202A is connected to a first side of the interposer 204. At least one tall metal pillar 212A extends through the open area 220 of the interposer 204 that is connected to both the first die 202A and the second die 202B to provide a direct die-to-die connection through the interposer 204 without a via. In further detail, the first die 202A is shown with a tall metal pillar 212A extending through the open area 220 and connected (e.g., soldered) to the second die 202B through microbump 214A. Additionally or alternatively, the second die 202B may include at least one tall metal pillar 212B extending through the open area 220 and connected to the first die 202A through microbump 214B.

FIG. 2B depicts a simplified cross-sectional schematic diagram illustrating a semiconductor package where each of the dies includes tall metal pillars to provide a direct die-to-die connection through the open area in the interposer according to a further embodiment. The interposer 204 includes at least one open area 220 through the interposer 204. The first die 202A is connected to a first side of the interposer 204. The first die 202A has a first tall metal pillar 212A connected (e.g., soldered) to a first microbump 214A, where the first tall pillar 212A extends through the open area 220 of the interposer 204. The second die 202B is connected to the second side of the interposer 204. The second die 202B includes a second tall metal pillar 212B connected to a second microbump 214B, where the second tall metal pillar 212B extends through the open area 220 of the interposer 204. The first microbump 214A of the first die 202A and the second microbump 214B of the second die 202B are connected together to provide the direct die-to-die connection through the interposer 204 without the use of vias. Alternatively, there could be also only one microbump connecting metal pillars 212A and 212B and the dies 202A and 202B together.

In embodiments, both the tall pillars 212 and the microbumps 214 and 218 comprise a metal, such as copper, and are soldered together. In embodiments, the tall pillars 212 may be plated. For example, the tall pillars 212 may comprise copper plated with Tin as one example.

In embodiments, a tall metal pillar may have a height of approximately 50-125 μm and a diameter of 25-50 μm. In another embodiment, a tall metal pillar may have a height of approximately 100-300 μm. This is in contrast to a conventional vias and pillars. A conventional via are small holes are used, for example, to connect the adjacent RDLs. Vias may range in height from 5-10 μm on a silicon-based interposer, and may range in height from 30-50 μm on an organic-based interposer. A via may have a diameter of approximately 2 μm on a silicon interposer, and approximately 10-40 μm on an organic-based interposer. Conventional pillars are similar to vias, but they are relatively taller and have a larger diameter. Pillars may be used to connect multiple RDLs. In contrast, the tall metal pillars (hereinafter referred to simply as tall pillars) of the disclosed embodiments connect two dies through a width of an interposer (i.e., all the RDLs) or other substrate.

As will be appreciated by those of ordinary skill in the art, each of the first die 202A and the second die 202B include internal die pads 216 to which the tall pillar(s) 212 is/are connected. As also shown, the first die 202A and the second die 202B are connected to opposite sides of the interposer 204 with respective sets of microbumps 218. The microbumps 214 and 218 may comprise a material that is weaker than copper and can be squeezed and melted, such as solder.

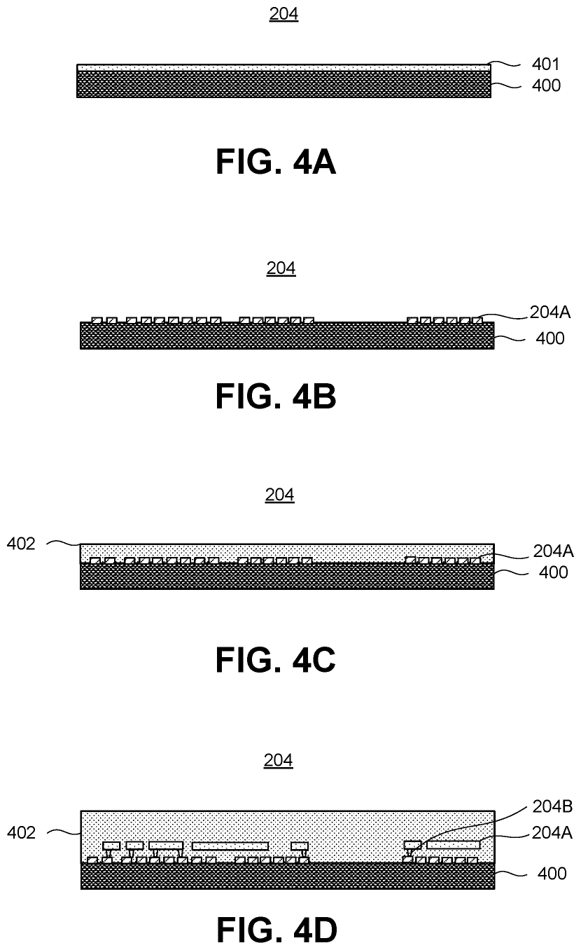

As an exemplary processing scheme involving the fabrication of a structure of a semiconductor package having a direct die-to-die connection through an interposer without vias, refer to the following FIGS. 3A-3D illustrating views of various stages in a method of fabricating a direct die-to-die connection through an interposer in accordance with an embodiment of the present disclosure, where like components from FIGS. 2A-2B have like reference numerals.

FIG. 3A illustrates a top view and cross-sectional view of interposer 204. As shown, the process includes fabricating the interposer 204 with one or more open areas 220 cut through the interposer 204 and fabricating one or more arrays of microbumps 218. Alternatively or additionally, the open areas 220 may be cut out of the interposer 204 after manufacture.

FIG. 3B illustrates the method for fabricating the structure of a semiconductor package further includes fabricating a first die 202A with a first set of die pads 216A and a first set of one or more tall pillars 212A attached to a first set of pillar microbumps 214A. A second die 202B is fabricated with a second set of die pads 216B and a second set of one or more tall pillars 212B optionally attached to a second set of pillar microbumps 214B. In embodiments, the first set of tall pillars 212A and the second set of tall pillars 212B may be manufactured with a height greater than 100 μm, pitches below 100 μm, and a diameter of 25-50 μm.

FIG. 3C illustrates the structure 300 of the semiconductor package after the first die 202A is attached to a first side of the interposer 204 using the first set of microbumps 218A such that the first set of one or more tall pillars 212A is inserted into the open area 220 of the interposer 204. Also shown is a third set of tall pillars 312 attached to a second side of the interposer 204.

FIG. 3D illustrates the structure 300 of the semiconductor package after the second die 202B is attached to a second side of the interposer 204 using the second set of microbumps 218B such that the set of one or more tall pillars 212B is inserted into the open area 220 of the interposer 204. The first set of pillars microbumps and the second set of microbump pillars are attached together to provide a direct die-to-die connection through the interposer 204. FIG. 3D further illustrates that after the direct die-to-die connection is made, the interposer 204 may be attached to a substrate 304.

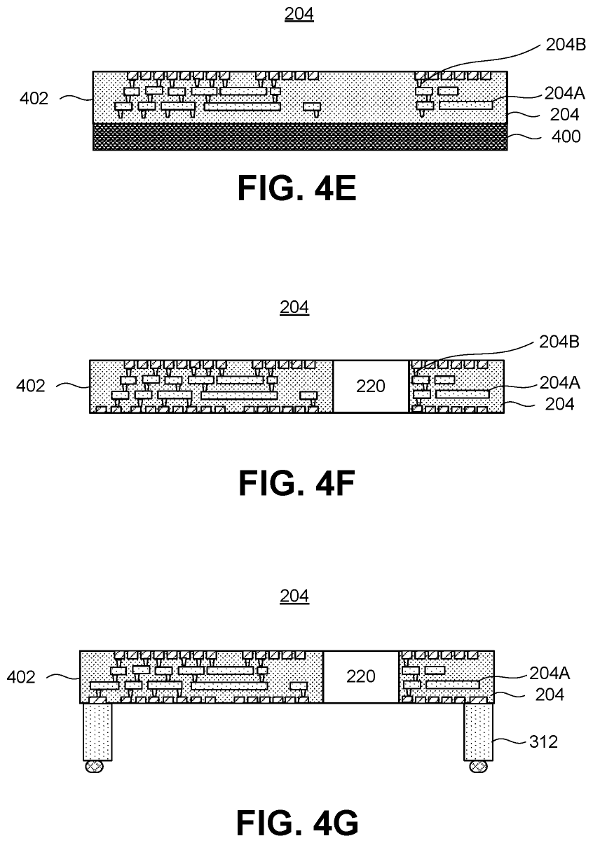

FIGS. 4A-4G illustrate the further details for fabricating the interposer 204 with at least one open area. FIG. 4A shows a manufacturing process where copper layers 401 are deposited over a carrier 400, which may comprise a silicon, glass, or an organic material.

FIG. 4B shows that patterns formed in the copper layers 401 using, for example, a lithography patterning process, to form interconnects 204A in a redistribution layer (RDL). In one embodiment, at least one area of the interposer 204 is reserved with no copper layers, which will later be cut out.

FIG. 4C shows that a photoresist 402 is deposited over the interconnects 204A.

FIG. 4D shows that another RDL with interconnects 204A and vias 204B is formed over the photoresist 402.

FIG. 4E show that the process of depositing photoresist 402 and forming RDLs is repeated as desired to build up the interposer 204.

FIG. 4F shows that after the carrier 400 is broken off, the area with no copper layers in the interposer 204 is wet etched or lasered away to a depth of the interposer 204 to form open area 220.

FIG. 4G shows that interposer 204 is complete after a conductive material, e.g., copper, is deposited to form the set of tall pillars 312 and/or contacts. In one embodiment, the conductive material may be formed with a copper electroplating process, sputtered copper, or the like.

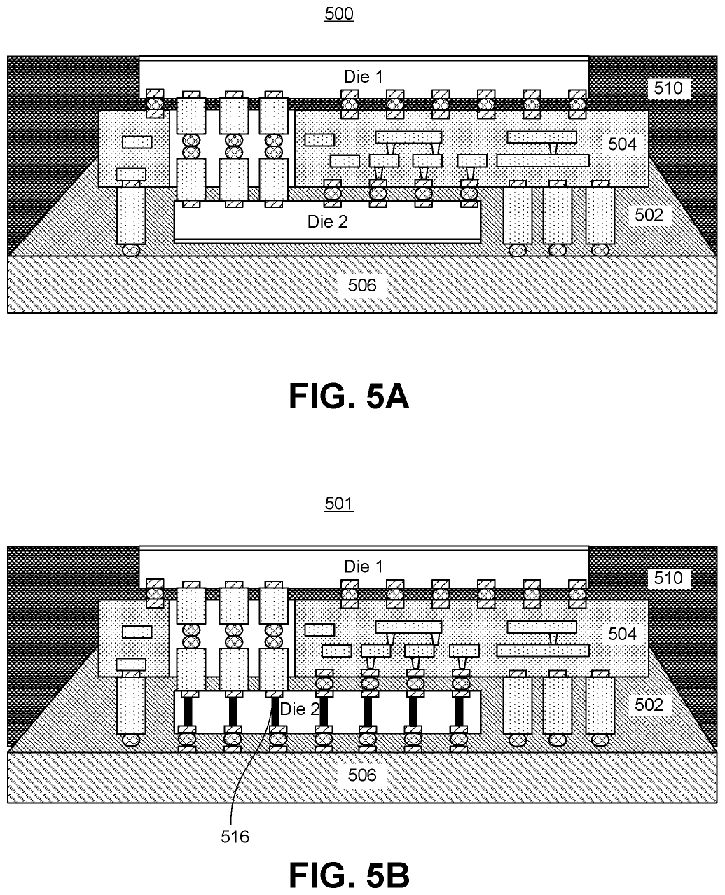

FIGS. 5A-5C illustrate simplified cross-sectional schematic diagrams illustrating a semiconductor package in various embodiments.

FIG. 5A depicts an embodiment of a complete semiconductor package 500 where interposer 504 is connected to substrate 506 through the set of tall pillars 312. This embodiment shows a package forward to the substrate to die 1 and an interconnect between the substrate 506 and die 2 is bypassed, i.e., die 2 is not directly connected to the substrate. Instead, the substrate 506 is connected to die 1 through die 2 by the direct die-to-die connection through the interposer 504. An underfill 502 is formed around the bottom side of interposer 504 and die 2 under the interposer 504, and an overmold 510 is over the underfill 502 that covers the top of the interposer 504 and die 1. Alternatively, it is possible to skip the underfill and fill the gap with a molded underfill to use only one mold material

FIG. 5B depicts an embodiment identical to that shown in FIG. 5A showing the dies 1 and 2 that may or may not have through-silicon vias (TSVs) 516. A TSV is a vertical electrical interconnection that passes through the die and extends down to a substrate or another die in a stacked or 3D integrated circuit configuration. For example, die 1 is shown without a TSV, and die 2 is shown including TSVs 516 connected to substrate 506 for improved electrical connection.

FIG. 5C depicts an embodiment of semiconductor package 503 where one die (e.g. die 2) on one side of interposer 504 is directly connected to multiple dies (e.g., dies 1 and 3) on the opposite side of interposer 504 by the direct die-to-die connections. In this embodiment, die 3 is also on the top side of the interposer with another set of tall pillars connected between die 2 and die 3 through a second open area in the interposer 504, such that the die 2 acts a bridge die between the die 1 and die 3. Also, die 2 in this embodiment is shown with TSVs 516 to improve the connections to die 1 and die 3. The dies 1 and 3 may or may not have TSVs. With known technology die 1 and 3 can be bridged, but the bridge would be formed on the same side (e.g., the top side) of the interposer. In this example, the bridge for dies 1 and 3 on the top side is formed on the back side of the interposer using direct connections between die 2 to both dies 1 and 3.

The embodiments shown in FIGS. 5A-5C have in common a direct connection from one die to another through one or more tall pillars that extend through an open area in the interposer. Also, the height of the tall pillars, which may also be referred to as through interposer pillars, can be different for, e.g., thermomechanical or assembly yield improvements. Finally, the system is normally encapsulated with, for example, underfill and epoxy mold compound for moisture and mechanical protection, which can be full or partial.

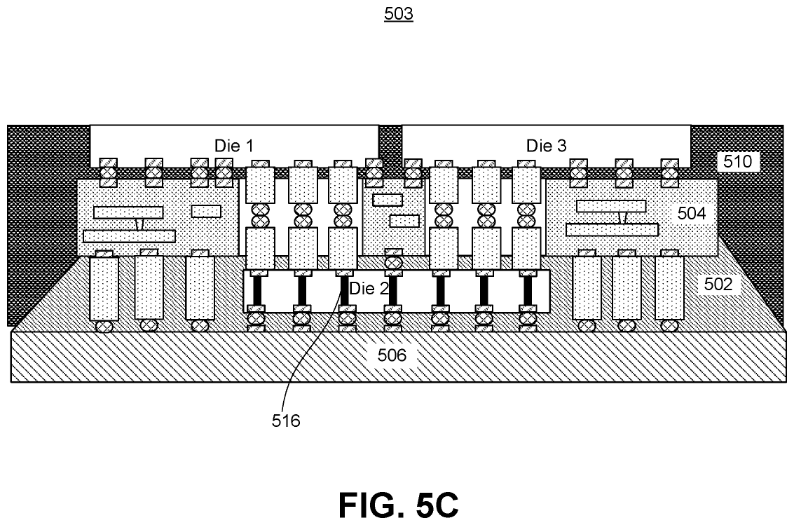

Referring to FIGS. 6A and 6B, a wafer 600 may be composed of semiconductor material and may include one or more dies 602 having integrated circuit (IC) structures formed on the surface of the wafer 600. Each of the dies 602 may be a repeating unit of a semiconductor product that includes any suitable IC (e.g., ICs including a substrate with direct die-two-die connection through an interposer without vias, such as described above. After the fabrication of the semiconductor product is complete, the wafer 600 may undergo a singulation process in which each of the dies 602 is separated from one another to provide discrete “chips” of the semiconductor product. In particular, structures that include embedded non-volatile memory structures having a substrate with direct die-two-die connection through an interposer without vias, as disclosed herein may take the form of the wafer 600 (e.g., not singulated) or the form of the die 602 (e.g., singulated). The die 602 may include one or more embedded non-volatile memory structures and/or supporting circuitry to route electrical signals, as well as any other IC components. In some embodiments, the wafer 600 or the die 602 may include an additional memory device (e.g., a static random access memory (SRAM) device), a logic device (e.g., an AND, OR, NAND, or NOR gate), or any other suitable circuit element. Multiple ones of these devices may be combined on a single die 602. For example, a memory array formed by multiple memory devices may be formed on the same die 602 as a processing device or other logic that is configured to store information in the memory devices or execute instructions stored in the memory array.

Embodiments disclosed herein may be used to manufacture a wide variety of different types of integrated circuits and/or microelectronic devices. Examples of such integrated circuits include, but are not limited to, processors, chipset components, graphics processors, digital signal processors, micro-controllers, and the like. In other embodiments, semiconductor memory may be manufactured. Moreover, integrated circuits or other microelectronic devices may be used in a wide variety of electronic devices known in the arts. For example, in computer systems (e.g., desktop, laptop, server), cellular phones, personal electronics, etc. The integrated circuits may be coupled with a bus and other components in the systems. For example, a processor may be coupled by one or more buses to a memory, a chipset, etc. Each of the processor, the memory, and the chipset, may potentially be manufactured using the approaches disclosed herein.

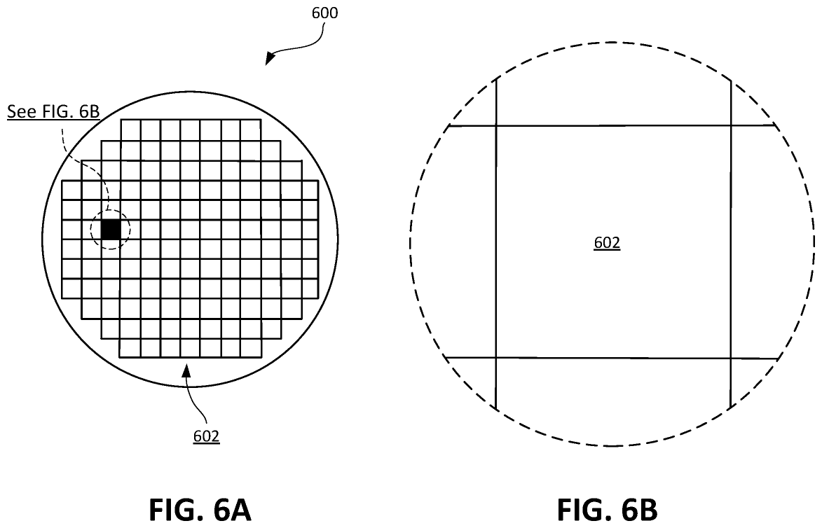

FIG. 7 illustrates a block diagram of an electronic system 700, in accordance with an embodiment of the present disclosure. The electronic system 700 can correspond to, for example, a portable system, a computer system, a process control system, or any other system that utilizes a processor and an associated memory. The electronic system 700 may include a microprocessor 702 (having a processor 704 and control unit 706), a memory device 708, and an input/output device 710 (it is to be appreciated that the electronic system 700 may have a plurality of processors, control units, memory device units and/or input/output devices in various embodiments). In one embodiment, the electronic system 700 has a set of instructions that define operations that are to be performed on data by the processor 704, as well as, other transactions between the processor 704, the memory device 708, and the input/output device 710. The control unit 706 coordinates the operations of the processor 704, the memory device 708 and the input/output device 710 by cycling through a set of operations that cause instructions to be retrieved from the memory device 708 and executed. The memory device 708 can include a non-volatile memory cell as described in the present description. In an embodiment, the memory device 708 is embedded in the microprocessor 702, as depicted in FIG. 7. In an embodiment, the processor 704, or another component of electronic system 700, includes a substrate with direct die-two-die connection through an interposer without vias, such as those described herein.

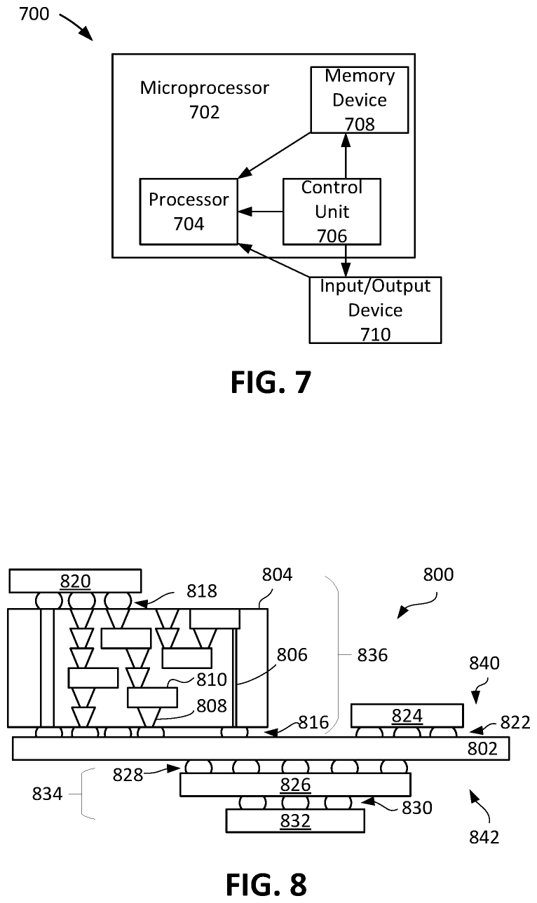

FIG. 8 is a cross-sectional side view of an integrated circuit (IC) device assembly that may include a substrate with direct die-two-die connection through an interposer without vias, in accordance with one or more of the embodiments disclosed herein.

Referring to FIG. 8, an IC device assembly 800 includes components having one or more integrated circuit structures described herein. The IC device assembly 800 includes a number of components disposed on a circuit board 802 (which may be, e.g., a motherboard). The IC device assembly 800 includes components disposed on a first face 840 of the circuit board 802 and an opposing second face 842 of the circuit board 802. Generally, components may be disposed on one or both faces 840 and 842. In particular, any suitable ones of the components of the IC device assembly 800 may include a number of a multilayer high-k gate dielectric, such as disclosed herein.

In some embodiments, the circuit board 802 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 802. In other embodiments, the circuit board 802 may be a non-PCB substrate.

The IC device assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802, and may include solder balls (as shown in FIG. 8), male and female portions of a socket, an adhesive, an underfill material, and/or any other suitable electrical and/or mechanical coupling structure.

The package-on-interposer structure 836 may include an IC package 820 coupled to an interposer 804 by coupling components 818. The coupling components 818 may take any suitable form for the application, such as the forms discussed above with reference to the coupling components 816. Although a single IC package 820 is shown in FIG. 8, multiple IC packages may be coupled to the interposer 804. It is to be appreciated that additional interposers may be coupled to the interposer 804. The interposer 804 may provide an intervening substrate used to bridge the circuit board 802 and the IC package 820. The IC package 820 may be or include, for example, a die (the die 602 of FIG. 6B), or any other suitable component. Generally, the interposer 804 may spread a connection to a wider pitch or reroute a connection to a different connection. For example, the interposer 804 may couple the IC package 820 (e.g., a die) to a ball grid array (BGA) of the coupling components 816 for coupling to the circuit board 802. In the embodiment illustrated in FIG. 8, the IC package 820 and the circuit board 802 are attached to opposing sides of the interposer 804. In other embodiments, the IC package 820 and the circuit board 802 may be attached to the same side of the interposer 804. In some embodiments, three or more components may be interconnected by way of the interposer 804.

The interposer 804 may be formed of an epoxy resin, a fiberglass-reinforced epoxy resin, a ceramic material, or a polymer material such as polyimide. In some implementations, the interposer 804 may be formed of alternate rigid or flexible materials that may include the same materials described above for use in a semiconductor substrate, such as silicon, germanium, and other group III-V and group IV materials. The interposer 804 may include metal interconnects 810 and vias 808, including but not limited to through-silicon vias (TSVs) 806. The interposer 804 may further include embedded devices, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio-frequency (RF) devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art.

The IC device assembly 800 may include an IC package 824 coupled to the first face 840 of the circuit board 802 by coupling components 822. The coupling components 822 may take the form of any of the embodiments discussed above with reference to the coupling components 816, and the IC package 824 may take the form of any of the embodiments discussed above with reference to the IC package 820.

The IC device assembly 800 illustrated in FIG. 8 includes a package-on-package structure 834 coupled to the second face 842 of the circuit board 802 by coupling components 828. The package-on-package structure 834 may include an IC package 826 and an IC package 832 coupled together by coupling components 830 such that the IC package 826 is disposed between the circuit board 802 and the IC package 832. The coupling components 828 and 830 may take the form of any of the embodiments of the coupling components 816 discussed above, and the IC packages 826 and 832 may take the form of any of the embodiments of the IC package 820 discussed above. The package-on-package structure 834 may be configured in accordance with any of the package-on-package structures known in the art.

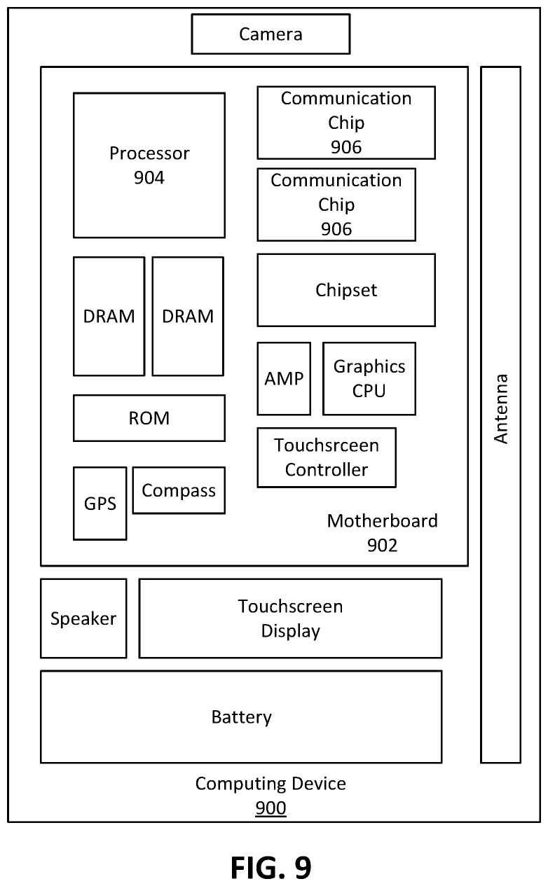

FIG. 9 illustrates a computing device 900 in accordance with one implementation of the disclosure. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

Depending on its applications, computing device 900 may include other components that may or may not be physically and electrically coupled to the board 902. These other components include, but are not limited to, volatile memory (e.g., DRAM), non-volatile memory (e.g., ROM), flash memory, a graphics processor, a digital signal processor, a cryptoprocessor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter-range wireless communications such as Wi-Fi and Bluetooth and a second communication chip 906 may be dedicated to longer-range wireless communications such as GPS, EDGE, GPRS, CDMA, WiMAX, LTE, Ev-DO, and others.

The processor 904 of the computing device 900 includes an integrated circuit die packaged within the processor 904. In some implementations of the disclosure, the integrated circuit die of the processor includes a substrate with direct die-two-die connection through an interposer without vias, in accordance with implementations of embodiments of the disclosure. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of embodiments of the disclosure, the integrated circuit die of the communication chip 906 includes a substrate with direct die-two-die connection through an interposer without vias, in accordance with implementations of embodiments of the disclosure.

In further implementations, another component housed within the computing device 900 may contain an integrated circuit die that includes a substrate with direct die-two-die connection through an interposer without vias, in accordance with implementations of embodiments of the disclosure.

In various implementations, the computing device 900 may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device 900 may be any other electronic device that processes data.

Thus, embodiments described herein include a direct die-two-die connection through an interposer without vias.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above-detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example embodiment 1: A semiconductor package comprises an interposer with at least one open area through the interposer. A first die is connected to a first side of the interposer. A second die is connected to a second side of the interposer. At least one metal pillar is connected to the first die that extends through the open area of the interposer and connects to the second die.

Example embodiment 2: The semiconductor package of embodiment 1, wherein the at least one metal pillar is approximately 50-125 μm in height.

Example embodiment 3: The semiconductor package of embodiment 1, wherein the at least one metal pillar is approximately 100-300 μm in height.

Example embodiment 4: The semiconductor package of embodiment 1, 2, or 3, wherein the at least one metal pillar is approximately 25-50 μm in diameter.

Example embodiment 5: The semiconductor package of 1, 2, 3, or 4, wherein the interposer is connected to a substrate through a set of metal pillars.

Example embodiment 6: The semiconductor package of embodiment 1, 2, 3, 4, or 5, wherein the first die is on a top side of the interposer, the second die is on a bottom side of the interposer, the substrate is connected to the first die through the second die by a direct die-to-die connection, and the second die is not connected to the substrate.

Example embodiment 7: The semiconductor package of embodiment 6, wherein the second die includes through-silicon vias (TSVs) to the substrate.

Example embodiment 8: The semiconductor package of embodiment 6 or 7, further including a third die on the top side of the interposer with at least one second metal pillar connected between the second die and the third die through a second open area in the interposer such that the second die acts a bridge die between the first die and the third die.

Example embodiment 9: A semiconductor package comprises an interposer with at least one open area through the interposer. A first die is connected to a first side of the interposer, the first die having a first metal pillar connected to a first microbump, first metal pillar extending through the open area of the interposer. A second die is connected to a second side of the interposer, the second die including a second metal pillar extending through the open area of the interposer and connected to the microbump.

Example embodiment 10: The semiconductor package of embodiment 9, wherein the metal pillar and second metal pillar are approximately 50-125 μm in height.

Example embodiment 11: The semiconductor package of embodiment 9, wherein the first metal pillar and second metal pillar are approximately 100-300 μm in height.

Example embodiment 12: The semiconductor package of embodiment 9, 10, or 11, wherein the first metal pillar and second metal pillar are approximately 25-50 μm in diameter.

Example embodiment 13: The semiconductor package of embodiment 9, 10, 11, or 12, wherein the interposer is connected to a substrate through a set of metal pillars, and wherein the first die is on a top side of the interposer, the second die is on a bottom side of the interposer, the substrate is connected to the first die through the second die by a direct die-to-die connection, and the second die is not connected to the substrate.

Example embodiment 14: The semiconductor package of embodiment 13, further comprising: a third die on the top side of the interposer with a third metal pillar connected between the second die and the third die through a second open area in the interposer such that the second die acts a bridge die between the first die and the third die.

Example embodiment 15: A method of fabricating a structure of a semiconductor package comprises fabricating an interposer with at least one open area through the interposer. A first die is fabricated with a first set of die pads and a first set of one or more metal pillars attached to a set of pillar microbumps. A second die is fabricated with a second set of die pads and a second set of one or more metal pillars. The first die is attached to a first side of the interposer using the set of die pads sand the first set of metal pillars is inserted into the open area of the interposer. The second die is attached to a second side of the interposer using the second set of die pads and the second set of metal pillars is inserted into the open area of the interposer. The first set of one or more metal pillars is attached to the second set of metal pillars by the set of pillar microbumps.

Example embodiment 16: The method of embodiment 15, further comprising: forming the first set of metal pillars and the second set of metal pillars to approximately 50-125 μm in height.

Example embodiment 17: The semiconductor package of embodiment 15, forming the first set of metal pillars and the second set of metal pillars to approximately 100-300 μm in height.

Example embodiment 18: The semiconductor package of embodiment 15 or 16, further comprising forming the first set of metal pillars and the second set of metal pillars to approximately 25-50 μm in diameter.

Example embodiment 19: The method of embodiment 15, 16, 17, or 18, further comprising: after the direct die-to-die connection is made, attaching the interposer to a substrate.

Example embodiment 20: The method of embodiment 19, further comprising: forming a third die on a top side of the interposer with a third set of metal pillars connected between the second die and the third die through a second open area in the interposer such that the second die acts a bridge die between the first die and the third die.

What is claimed is:

1. A semiconductor package comprising:
an interposer with at least one open area through the interposer;
a first die connected to a first side of the interposer;
a second die connected to a second side of the interposer; and
at least one metal pillar connected to the first die that extends through the open area of the interposer and connects to the second die.

2. The semiconductor package of claim 1, wherein the at least one metal pillar is approximately 50-125 μm in height.

3. The semiconductor package of claim 1, wherein the at least one metal pillar is approximately 100-300 μm in height.

4. The semiconductor package of claim 1, wherein the at least one metal pillar is approximately 25-50 μm in diameter.

5. The semiconductor package of 1, wherein the interposer is connected to a substrate through a set of metal pillars.

6. The semiconductor package of claim 5, wherein the first die is on a top side of the interposer, the second die is on a bottom side of the interposer, the substrate is connected to the first die through the second die by a direct die-to-die connection, and the second die is not connected to the substrate.

7. The semiconductor package of claim 6, wherein the second die includes through-silicon vias (TSVs) to the substrate.

8. The semiconductor package of claim 6, further including a third die on the top side of the interposer with at least one second metal pillar connected between the second die and the third die through a second open area in the interposer such that the second die acts a bridge die between the first die and the third die.

9. A semiconductor package comprising:
an interposer with at least one open area through the interposer;
a first die connected to a first side of the interposer, the first die having a first metal pillar connected to a microbump, first metal pillar extending through the open area of the interposer; and
a second die connected to a second side of the interposer, the second die including a second metal pillar extending through the open area of the interposer and connected to the microbump.

10. The semiconductor package of claim 9, wherein the metal pillar and second metal pillar are approximately 50-125 μm in height.

11. The semiconductor package of claim 9, wherein the first metal pillar and second metal pillar are approximately 100-300 μm in height.

12. The semiconductor package of claim 9, wherein the first metal pillar and second metal pillar are approximately 25-50 μm in diameter.

13. The semiconductor package of claim 9, wherein the interposer is connected to a substrate through a set of metal pillars, and wherein the first die is on a top side of the interposer, the second die is on a bottom side of the interposer, the substrate is connected to the first die through the second die by the direct die-to-die connection, and the second die is not connected to the substrate.

14. The semiconductor package of claim 13, further comprising: a third die on the top side of the interposer with a third metal pillar connected between the second die and the third die through a second open area in the interposer such that the second die acts a bridge die between the first die and the third die.

15. A method of fabricating a structure of a semiconductor package, the method comprising:
fabricating an interposer with at least one open area through the interposer;
fabricating a first die with a first set of die pads and a first set of one or more metal pillars attached to a set of pillar microbumps;
fabricating a second die with a second set of die pads and a second set of one or more metal pillars;
attaching the first die to a first side of the interposer using the first set of die pads and inserting the first set of metal pillars into the open area of the interposer;
attaching the second die to a second side of the interposer using the second set of die pads and inserting the second set of metal pillars into the open area of the interposer; and
attaching the first set of one or more metal pillars to the second set of metal pillars by the set of pillar microbumps.

16. The method of claim 15, further comprising: forming the first set of metal pillars and the second set of metal pillars to approximately 50-125 μm in height.

17. The semiconductor package of claim 15, forming the first set of metal pillars and the second set of metal pillars to approximately 100-300 μm in height.

18. The semiconductor package of claim 15, further comprising forming the first set of metal pillars and the second set of metal pillars to approximately 25-50 μm in diameter.

19. The method of claim 15, further comprising: attaching the interposer to a substrate.

20. The method of claim 19, further comprising: forming a third die on a top side of the interposer with a third set of metal pillars connected between the second die and the third die through a second open area in the interposer such that the second die acts a bridge die between the first die and the third die.
